(19) United States
(12) Patent Application Publication
(10) Pub. No.: US 2021/0043746 A1
(43) Pub. Date: Feb. 11, 2021

(54) THIN FILM TRANSISTOR AND MANUFACTURING METHOD THEREOF

(71) Applicant: TCL CHINA STAR OPTOELECTRONICS TECHNOLOGY CO., LTD, Shenzhen, Guangdong (CN)

(72) Inventor: Jing LIU, Shenzhen, Guangdong (CN)

(21) Appl. No.: 16/616,509

(22) PCT Filed: Sep. 9, 2019
(86) PCT No.: PCT/CN2019/104861

§ 371 Date: Nov. 25, 2019

(30) Foreign Application Priority Data
Aug. 5, 2019 (CN) 201910716466.4

(51) Int. Cl. H01L 29/49; H01L 29/786; H01L 21/28; H01L 21/3213; H01L 21/4763; H01L 29/66

(52) U.S. Cl. CPC H01L 29/4908; H01L 29/78669; H01L 29/7869; H01L 29/66969; H01L 21/32134; H01L 21/47635; H01L 29/66765; H01L 21/28088

(57) ABSTRACT

The present invention discloses a thin film transistor and manufacturing method thereof, comprising in sequence a substrate, a gate, a gate insulation layer, an active layer, a contact layer and a source/drain, wherein, the gate comprises a metal barrier layer and a conductive layer, the metal barrier layer is a molybdenum alloy layer, the molybdenum alloy layer comprises a Mo and two other metal elements.

### FIELD OF INVENTION

The disclosure relates to a display field, and more particularly to a thin film transistor and manufacturing method thereof.

### BACKGROUND OF INVENTION

Thin film transistors (TFTs) are commonly used as switching elements in semiconductor processes. In general, a thin film transistor comprises a gate, a gate insulating layer, a channel layer, a source, and a drain. Wherein, the gate, the source and the drain are respectively a single metal layer or a metal lamination composed of Al, Cr, Cu, W, Ta, Ti, or the like. Among the above conductive materials, Cu is widely used in an electrode structure of a thin film transistor such as a gate electrode, a source or a drain due to advantages such as low resistivity and good etching characteristics. The gate insulating layer is made of materials such as SiO2 and Si3N4.

With development of liquid crystal panels towards larger sizes, copper processes have been widely used in liquid crystal panel processes. In the process of manufacturing the gate, in order to increase adhesion of copper to the substrate and to inhibit diffusion of copper, a metal molybdenum barrier layer is usually sputtered on the substrate, and then the conductive layer is sputtered. Although the conductive layer/molybdenum barrier layer has a better etch rate and forms a better taper angle, but in the process, the molybdenum barrier layer is easily oxidized and etched by the etching solution, causing an undercut phenomenon of the gate, and even the conductive layer is hollowed out.

Specifically, the undercut phenomenon of the gate will make the thin film transistor work abnormally. Furthermore, when a structure of a conductive layer/molybdenum barrier layer is used to manufacturing wiring such as a scanning line or a data line connected to a thin film transistor, the above undercut phenomenon may increase impedance of the wiring, and may even cause an open circuit of the scanning line or the data line, thereby affecting component characteristics of the thin film transistor connected thereto and reducing product yield.

### SUMMARY OF INVENTION

The object of the present disclosure is to provide a thin film transistor and manufacturing method thereof, to resolve the problem that the undercut phenomenon occurs in the gate of the prior art, which affects the component characteristics of the thin film transistor and reduces product yield.

To achieve the above object, the present disclosure provides a thin film transistor, comprising a substrate, a gate, a gate insulation layer, an active layer, a contact layer and a source/drain; the gate is formed on the substrate; the gate insulation layer is formed on the gate; an active layer is formed on the gate insulation layer; a contact layer is formed on the active layer; and a source/drain is formed on the contact layer and the gate insulation, wherein the gate comprises a metal barrier layer and a conductive layer, the metal barrier layer is a molybdenum alloy layer, the molybdenum alloy layer comprises a Mo and two other metal elements.

Further, the two other metal elements are any two of W, Nd, Nb, and Ta.

Further, the molybdenum alloy layer is a MoNbTa ternary alloy, wherein the Ta has a weight percentage ranging from 0.05% to 20%.

Further, the molybdenum alloy layer is a MoNbNi ternary alloy, wherein the Ni has a weight percentage ranging from 0.05% to 50%.

Further, the Mo of the molybdenum alloy layer has a weight percentage ranging from 30% to 95%, and other two metal elements have a weight percentage ranging from 0.10% to 40%.

Further, the active layer is alpha-si (a-Si) or indium gallium zinc oxide (IGZO).

To achieve the above object, the present disclosure provides a method for manufacturing thin film transistor, comprising the steps as below, a substrate providing step, providing a substrate; a gate manufacturing step, manufacturing a gate on an upper surface of the substrate; a gate insulation layer manufacturing step, manufacturing a gate insulation layer on an upper surface of the gate; an active layer manufacturing step, manufacturing an active layer on an upper surface of the gate insulation layer; a contact layer manufacturing step, manufacturing a contact layer on an upper surface of the active layer; and a source/drain manufacturing step, manufacturing a source/drain on an upper surface of the contact layer and the gate insulation; wherein, the gate layer manufacturing step comprises the step as below, a metal barrier layer manufacturing step, manufacturing a metal barrier layer on an upper surface of the substrate; and a conductive layer manufacturing step, manufacturing a conductive layer on an upper surface of the metal barrier layer.

Further, the two other metal elements are any two of W, Nd, Nb, and Ta.

Further, the Mo of the molybdenum alloy layer has a weight percentage ranging from 30% to 95%, and other two metal elements have a weight percentage ranging from 0.10% to 40%.

Further, the conductive layer and the metal barrier layer are etched by a copper acid etching solution of a hydrogen peroxide system to form a patterned gate.

The results of the present disclosure are to provide a thin film transistor and manufacturing method thereof, the gate comprises a metal barrier layer and a conductive layer, the metal barrier layer is a molybdenum alloy layer, the molybdenum alloy layer may be one of the MoNbTa ternary alloy and MoNbNi ternary alloy, the molybdenum alloy layer can increase the adhesion of the conductive layer to the substrate, avoiding the undercut phenomenon occurs in the gate of the processes, to ensure the normal operation of the thin film transistor and to maintain its component characteristics, thereby improving the yield of the display panel.

### DESCRIPTION OF DRAWINGS

In order to more clearly illustrate the technical solutions of the embodiments of the present invention, the drawings used in the description of the embodiments will be briefly described as below, apparently, the drawings described as below are just some embodiments of the present invention, for the person having ordinary skill in the art, under the premise of no creative labor, the other drawings also can be obtained according to these drawings.

FIG. 1 is a schematic view of the thin film transistor.

FIG. 2 is a flow chart of the manufacturing method of the thin film transistor.

FIG. 3 is a flow chart of the gate manufacturing step.

FIG. 4 is a flow chart of the source/drain manufacturing step.

The some of signs of drawings as below: a substrate 1, a gate 2, a gate insulation layer 3, an active layer 4, a contact layer 5, a source/drain 6, a metal barrier layer 21, a conductive layer 33, a first metal layer 61 and a second metal layer 62.

### DETAILED DESCRIPTION OF PREFERRED EMBODIMENTS

The following description of every embodiment with reference to the accompanying drawings is used to exemplify a specific embodiment, which may be carried out in the present invention. The embodiments completely introduce the present disclosure for person having ordinary skill in the art, which makes technology content clear and understand. The present disclosure embodies through different types of the embodiment. The protection range of the present disclosure is not limited in the embodiment of the present disclosure.

The terminologies “first”, “second”, etc. in the specification, claims and aforesaid figures of the present invention are used for distinguishing different objects but not for describing the specific sequence. It is to be understood that the terms so used are interchangeable under appropriate circumstances. Furthermore, the terms “comprising” and its any deformations are intended to cover non-exclusive inclusion.

### Embodiment 1

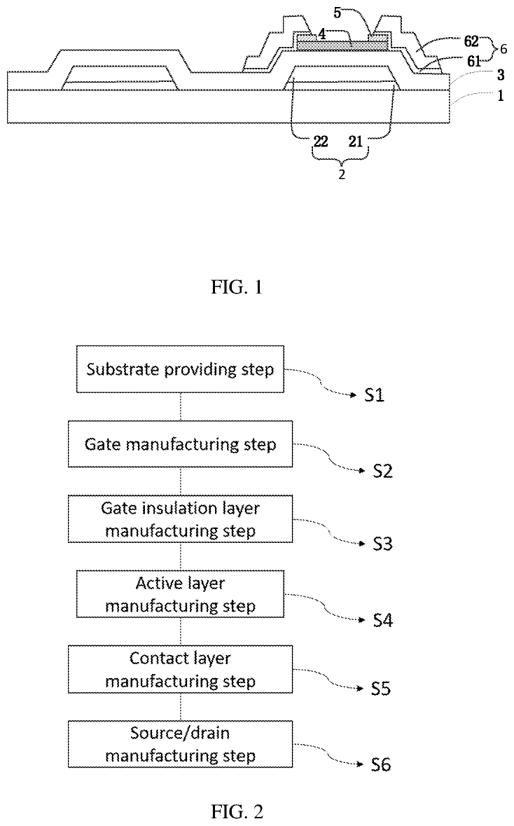

As shown as FIG. 1, the present disclosure provides a thin film transistor, comprising a substrate, a substrate 1, a gate 2, a gate insulation layer 3, an active layer 4, a contact layer 5, a source/drain 6; the gate 2 is formed on the substrate 1; the gate insulation layer 3 is formed on the gate 2; an active layer 4 is formed on the gate insulation layer 3; a contact layer 5 is formed on the active layer 4; and a source/drain 6 is formed on the contact layer 5 and the gate insulation 3.

The substrate 1 may be a glass substrate, a quartz substrate or other kind of substrate.

The gate 2 comprises a metal barrier layer 21 and a conductive layer 22, the metal barrier layer 21 is a molybdenum alloy layer, the molybdenum alloy layer comprises a Mo and two other metal elements. The two other metal elements are any two of W, Nd, Nb, and Ta. The Mo of the molybdenum alloy layer has a weight percentage ranging from 30% to 95%, and other two metal elements have a weight percentage ranging from 0.10% to 40%. In the present embodiment, the MoNbTa ternary alloy and the MoNbNi ternary alloy will be described, but not limited to other ternary alloys.

When the molybdenum alloy layer is MoNbTa ternary alloy, the Mo has a weight percentage ranging from 60% to 90%, the Nb has a weight percentage ranging from 0.05% to 20% and the Ta has a weight percentage ranging from 0.05% to 20%. In the prior art, since pure molybdenum is hard and tough, but in the wet etching process, the corrosion resistance of pure molybdenum is not good. In the present embodiment, the Mo is used as a matrix to form a metal barrier layer 21 by adding a Nb and a Ta. The metal barrier layer 21 is harder and tougher than the pure molybdenum material, and has strong corrosion resistance. In the present embodiment, the metal barrier layer 21 is composed of 84% by weight of Mo, 10% by weight of Nb, and 6% by weight of Ta, compared with the prior art, the metal barrier layer 21 has greater acid and alkali corrosion resistance than the pure molybdenum material and has the best wet etching characteristics, avoiding the undercut phenomenon and improving the yield of the display panel.

When the molybdenum alloy layer is MoNbNi ternary alloy, the Mo has a weight percentage ranging from 30% to 95%, the Nb has a weight percentage ranging from 0.05% to 20% and the Ta has a weight percentage ranging from 0.05% to 20%. In the prior art, since pure molybdenum is hard and tough, but in the wet etching process, the corrosion resistance of pure molybdenum is not good. In the present embodiment, the Mo is used as a matrix to form a metal barrier layer 21 by adding a Nb and a Ni. The metal barrier layer 21 is harder and tougher than the pure molybdenum material, and has strong corrosion resistance. In the present embodiment, the metal barrier layer 21 is composed of 80% by weight of Mo, 10% by weight of Nb, and 10% by weight of Ni, compared with the prior art, the metal barrier layer 21 has greater acid and alkali corrosion resistance than the pure molybdenum material and has the best wet etching characteristics, avoiding the undercut phenomenon and improving the yield of the display panel.

In the present embodiment, the metal barrier layer 21 is a molybdenum alloy layer, the molybdenum alloy layer may be one of the MoNbTa ternary alloy and MoNbNi ternary alloy. The molybdenum metal layer in the present embodiment is compared with the molybdenum metal layer in the prior art, the corrosion resistance of the metal barrier layer 21 is much better than that of the pure molybdenum material, so the metal barrier layer 21 can effectively avoid the phenomenon that the pure molybdenum material is easily oxidized and corroded during the wet etching process. Furthermore, the gate is a structure of a metal barrier layer 21/conductive layer 22, the metal barrier layer 21 is disposed on the upper surface of the substrate 1, which can avoid the undercut phenomenon occurs in the gate of the processes and increase the adhesion of the conductive layer 22 to the substrate 1, to ensure the normal operation of the thin film transistor and to maintain its component characteristics, thereby improving the yield of the display panel.

The gate insulation layer 3 on an upper surface of the substrate 1 and the gate 2, the material of gate insulating layer 3 may be SiO2, Si3N4 or other dielectric materials.

The active layer 4 is disposed on the upper surface of the gate insulation layer 3 and the material of active layer is a-Si or IGZO.

The contact layer 5 is disposed on the upper surface of the active layer 4, and is disposed on both ends of the active layer 4 after being patterned. The material of the contact layer 5 is doped amorphous silicon, and may be n-type doped amorphous silicon or P-type doped amorphous silicon.

The source/drain 6 is disposed on the upper surfaces of the contact layer 5 and the gate insulating layer 3, and extend from the contact layer 5 to the gate insulating layer 3.

The source/drain 6 comprises a first metal layer 61 and a second metal layer 62.

The material of the first metal layer 61 may be a Mo or a molybdenum alloy, and the material of the second metal layer 32 is Cu. The material of the first metal layer 61 is preferably a molybdenum alloy, which can avoid the problem of undercut phenomenon of the source/drain 6 in the wet etching process during the manufacturing process. Therefore, the source/drain 6 is prevented from being damaged during the manufacturing process, thereby maintaining the component characteristics of the thin film transistor.

The present disclosure provides a thin film transistor, the metal barrier layer 21 is a molybdenum alloy layer, the molybdenum alloy layer may be one of the MoNbTa ternary alloy and MoNbNi ternary alloy. The molybdenum metal layer in the present embodiment is compared with the molybdenum metal layer in the prior art, the corrosion resistance of the metal barrier layer is much better than that of the pure molybdenum material, so the metal barrier layer can effectively avoid the phenomenon that the pure molybdenum material is easily oxidized and corroded during the wet etching process. Furthermore, the gate is a structure of a metal barrier layer/conductive layer the metal barrier layer is disposed on the upper surface of the substrate, which can avoid the undercut phenomenon occurs in the gate of the processes and increase the adhesion of the conductive layer to the substrate, to ensure the normal operation of the thin film transistor and to maintain its component characteristics, thereby improving the yield of the display panel.

As shown as FIG. 2, the present embodiment provides a method for manufacturing thin film transistor, comprising the steps as below S1 to S6.

S1 is a substrate providing step, providing a substrate. The substrate may be a glass substrate, a quartz substrate or other kind of substrate.

S2 is a gate manufacturing step, manufacturing a gate on an upper surface of the substrate.

S3 is a gate insulation layer manufacturing step, manufacturing a gate insulation layer on an upper surface of the gate. The material of gate insulating layer 3 may be SiO2, Si3N4 or other dielectric materials.

S4 is an active layer manufacturing step, deposition an active layer on an upper surface of the gate insulation layer, and the material of the active layer is a-Si or IGZO.

S5 is a contact layer manufacturing step, deposition a contact layer on an upper surface of the active layer, and the material of the contact layer is doped amorphous silicon, and may be n-type doped amorphous silicon or P-type doped amorphous silicon.

S6 is a source/drain manufacturing step, manufacturing a source/drain on an upper surface of the contact layer and the gate insulation.

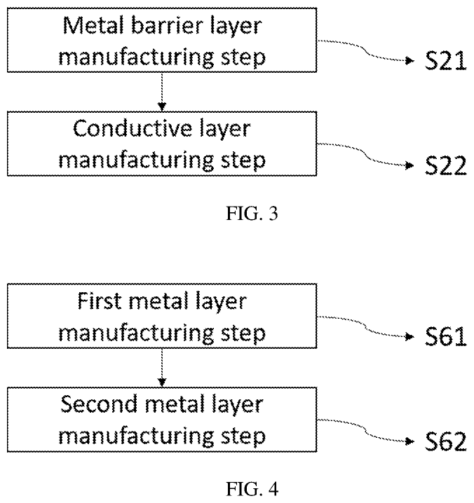

As shown as FIG. 3, the gate layer manufacturing step comprises the step as below S21 to S22. S21 is a metal barrier layer manufacturing step, manufacturing a metal barrier layer on an upper surface of the substrate, the metal barrier layer is a molybdenum alloy layer composed of a plurality of metals. Specifically, a metal barrier layer is sputtered on the upper surface of the substrate by magnetron sputtering, the material of metal barrier layer is a molybdenum alloy, the molybdenum alloy layer may be one of the MoNbTa ternary alloy and MoNbNi ternary alloy. Mo is a silver-white metal, hard and tough; the Nb has high ductility and hardens as the content of impurities increases; the Ta has extremely high corrosion resistance; the Ni has strong corrosion resistance. S22 is a conductive layer manufacturing step, a conductive layer is sputtered on the upper surface of the molybdenum alloy layer by magnetron sputtering. In the present embodiment, the conductive layer and the metal barrier layer are etched by a copper acid etching solution of a hydrogen peroxide system to form a patterned gate.

When the molybdenum alloy layer is MoNbTa ternary alloy, the Mo has a weight percentage ranging from 60% to 90%, the Nb has a weight percentage ranging from 0.05% to 20% and the Ta has a weight percentage ranging from 0.05% to 20%. In the prior art, since pure molybdenum is hard and tough, but in the wet etching process, the corrosion resistance of pure molybdenum is not good. In the present embodiment, the Mo is used as a matrix to form a metal barrier layer 21 by adding a Nb and a Ta. The metal barrier layer 21 is harder and tougher than the pure molybdenum material, and has strong corrosion resistance. In the present embodiment, the metal barrier layer 21 is composed of 84% by weight of Mo, 10% by weight of Nb, and 6% by weight of Ta, compared with the prior art, the metal barrier layer 21 has greater acid and alkali corrosion resistance than the pure molybdenum material and has the best wet etching characteristics, avoiding the undercut phenomenon and improving the yield of the display panel.

When the molybdenum alloy layer is MoNbNi ternary alloy, the Mo has a weight percentage ranging from 30% to 95%, the Nb has a weight percentage ranging from 0.05% to 20% and the Ta has a weight percentage ranging from 0.05% to 20%. In the prior art, since pure molybdenum is hard and tough, but in the wet etching process, the corrosion resistance of pure molybdenum is not good. In the present embodiment, the Mo is used as a matrix to form a metal barrier layer 21 by adding a Nb and a Ni. The metal barrier layer 21 is harder and tougher than the pure molybdenum material, and has strong corrosion resistance. In the present embodiment, the metal barrier layer 21 is composed of 80% by weight of Mo, 10% by weight of Nb, and 10% by weight of Ni, compared with the prior art, the metal barrier layer 21 has greater acid and alkali corrosion resistance than the pure molybdenum material and has the best wet etching characteristics, avoiding the undercut phenomenon and improving the yield of the display panel.

As shown as FIG. 4, the source/drain manufacturing step comprises the steps as below S61 to S62. S61 is a first metal layer manufacturing step, depositing a first metal layer on the upper surface of the substrate and the contact layer. The material of the first metal layer may be Mo, molybdenum alloy, preferably molybdenum alloy, which can avoid the undercut phenomenon of the source/drain in the wet etching process during the manufacturing process. Therefore, the source/drain is prevented from being damaged during the manufacturing process, thereby maintaining the component characteristics of the thin film transistor. S62 is a second metal layer manufacturing step, depositing a second metal layer on the upper surface of the first metal layer, and the material of the second metal layer 32 is Cu.

The present embodiment provides a thin film transistor and manufacturing method thereof, the gate comprises a metal barrier layer and a conductive layer, the metal barrier layer is a molybdenum alloy layer, the molybdenum alloy layer may be one of the MoNbTa ternary alloy and MoNbNi ternary alloy, the molybdenum alloy layer can increase the adhesion of the conductive layer to the substrate, avoiding the undercut phenomenon occurs in the gate of the processes, to ensure the normal operation of the thin film transistor and to maintain its component characteristics, thereby improving the yield of the display panel.

### Embodiment 2

The present embodiment provides a thin film transistor and manufacturing method thereof, comprising the most of the technical features of the thin film transistor and manufacturing method thereof in Embodiment 1, the distinctive feature is that, in embodiment 2, the metal barrier layer is composed of 65% by weight of Mo, 15% by weight of Nb, and 20% by weight of Ta or Ni, compared with the prior art, the metal barrier layer has greater acid and alkali corrosion resistance than the pure molybdenum material and has the best wet etching characteristics, avoiding the undercut phenomenon and improving the yield of the display panel.

### Embodiment 3

The present embodiment provides a thin film transistor and manufacturing method thereof, comprising the most of the technical features of the thin film transistor and manufacturing method thereof in Embodiment 1, the distinctive feature is that, in embodiment 3, the metal barrier layer is composed of 71% by weight of Mo, 11% by weight of Nb, and 18% by weight of Ta or Ni, compared with the prior art, the metal barrier layer has greater acid and alkali corrosion resistance than the pure molybdenum material and has the best wet etching characteristics, avoiding the undercut phenomenon and improving the yield of the display panel.

### Embodiment 4

The present embodiment provides a thin film transistor and manufacturing method thereof, comprising the most of the technical features of the thin film transistor and manufacturing method thereof in Embodiment 1, the distinctive feature is that, in embodiment 4, the metal barrier layer is composed of 76% by weight of Mo, 5% by weight of Nb, and 19% by weight of Ta or Ni, compared with the prior art, the metal barrier layer has greater acid and alkali corrosion resistance than the pure molybdenum material and has the best wet etching characteristics, avoiding the undercut phenomenon and improving the yield of the display panel.

### Embodiment 5

The present embodiment provides a thin film transistor and manufacturing method thereof, comprising the most of the technical features of the thin film transistor and manufacturing method thereof in Embodiment 1, the distinctive feature is that, in embodiment 5, the metal barrier layer is composed of 80% by weight of Mo, 2% by weight of Nb, and 18% by weight of Ta or Ni, compared with the prior art, the metal barrier layer has greater acid and alkali corrosion resistance than the pure molybdenum material and has the best wet etching characteristics, avoiding the undercut phenomenon and improving the yield of the display panel.

### Embodiment 6

The present embodiment provides a thin film transistor and manufacturing method thereof, comprising the most of the technical features of the thin film transistor and manufacturing method thereof in Embodiment 1, the distinctive feature is that, in embodiment 6, the metal barrier layer is composed of 85% by weight of Mo, 1% by weight of Nb, and 14% by weight of Ta or Ni, compared with the prior art, the metal barrier layer has greater acid and alkali corrosion resistance than the pure molybdenum material and has the best wet etching characteristics, avoiding the undercut phenomenon and improving the yield of the display panel.

### Embodiment 7

The present embodiment provides a thin film transistor and manufacturing method thereof, comprising the most of the technical features of the thin film transistor and manufacturing method thereof in Embodiment 1, the distinctive feature is that, in embodiment 7, the metal barrier layer is composed of 92% by weight of Mo, 3% by weight of Nb, and 5% by weight of Ta or Ni, compared with the prior art, the metal barrier layer has greater acid and alkali corrosion resistance than the pure molybdenum material and has the best wet etching characteristics, avoiding the undercut phenomenon and improving the yield of the display panel.

### Embodiment 8

The present embodiment provides a thin film transistor and manufacturing method thereof, comprising the most of the technical features of the thin film transistor and manufacturing method thereof in Embodiment 1, the distinctive feature is that, in embodiment 8, the metal barrier layer is composed of 90% by weight of Mo, 1% by weight of Nb, and 9% by weight of Ta or Ni, compared with the prior art, the metal barrier layer has greater acid and alkali corrosion resistance than the pure molybdenum material and has the best wet etching characteristics, avoiding the undercut phenomenon and improving the yield of the display panel.

### Embodiment 9

The present embodiment provides a thin film transistor and manufacturing method thereof, comprising the most of the technical features of the thin film transistor and manufacturing method thereof in Embodiment 1, the distinctive feature is that, in embodiment 8, the metal barrier layer is composed of 80% by weight of Mo, 8% by weight of Nb, and 7% by weight of Ta, compared with the prior art, the metal barrier layer has greater acid and alkali corrosion resistance than the pure molybdenum material and has the best wet etching characteristics, avoiding the undercut phenomenon and improving the yield of the display panel.

### Embodiment 10

The present embodiment provides a thin film transistor and manufacturing method thereof, comprising the most of the technical features of the thin film transistor and manufacturing method thereof in Embodiment 1, the distinctive feature is that, in embodiment 8, the metal barrier layer is composed of 85% by weight of Mo, 8% by weight of Nb, and 7% by weight of Ta, compared with the prior art, the metal barrier layer has greater acid and alkali corrosion resistance than the pure molybdenum material and has the best wet etching characteristics, avoiding the undercut phenomenon and improving the yield of the display panel.

### Embodiment 11

The present embodiment provides a thin film transistor and manufacturing method thereof, comprising the most of the technical features of the thin film transistor and manufacturing method thereof in Embodiment 1, the distinctive feature is that, in embodiment 8, the metal barrier layer is composed of 38% by weight of Mo, 19% by weight of Nb, and 43% by weight of Ni, compared with the prior art, the metal barrier layer has greater acid and alkali corrosion resistance than the pure molybdenum material and has the best wet etching characteristics, avoiding the undercut phenomenon and improving the yield of the display panel.

### Embodiment 12

The present embodiment provides a thin film transistor and manufacturing method thereof, comprising the most of the technical features of the thin film transistor and manufacturing method thereof in Embodiment 1, the distinctive feature is that, in embodiment 8, the metal barrier layer is composed of 46% by weight of Mo, 14% by weight of Nb, and 40% by weight of Ni, compared with the prior art, the metal barrier layer has greater acid and alkali corrosion resistance than the pure molybdenum material and has the best wet etching characteristics, avoiding the undercut phenomenon and improving the yield of the display panel.

### Embodiment 13

The present embodiment provides a thin film transistor and manufacturing method thereof, comprising the most of the technical features of the thin film transistor and manufacturing method thereof in Embodiment 1, the distinctive feature is that, in embodiment 8, the metal barrier layer is composed of 57% by weight of Mo, 8% by weight of Nb, and 35% by weight of Ni, compared with the prior art, the metal barrier layer has greater acid and alkali corrosion resistance than the pure molybdenum material and has the best wet etching characteristics, avoiding the undercut phenomenon and improving the yield of the display panel.

In the above embodiment, when the Mo has a weight percentage ranging from 30% to 95% of the molybdenum alloy, and the other two has a weight percentage ranging from 0.10% to 40%, the hardness of the metal barrier layer is greater than that of the pure molybdenum material, and the acid and alkali corrosion resistance is the best.

Although the present invention has been described with reference to the preferred embodiments thereof, it is noted that the person having ordinary skill in the art may appreciate improvements and modifications without departing from the principle of the present invention and those improvements and modifications are considered within the scope of protection of the present invention.

What is claimed is:

1. A thin film transistor, comprising:
a substrate;
a gate formed on the substrate;
a gate insulation layer formed on the gate;
an active layer formed on the gate insulation layer;
a contact layer formed on the active layer; and
a source/drain formed on the contact layer and the gate insulation;
wherein, the gate comprises a metal barrier layer and a conductive layer, the metal barrier layer is a molybdenum alloy layer, the molybdenum alloy layer comprises Mo and two other metal elements.

2. The thin film transistor as claimed in claimed 1, wherein the two other metal elements are any two of W, Nd, Nb, and Ta.

3. The thin film transistor as claimed in claimed 1, wherein the molybdenum alloy layer is a MoNbTa ternary alloy, wherein the Ta has a weight percentage ranging from 0.05% to 20%.

4. The thin film transistor as claimed in claimed 1, wherein the molybdenum alloy layer is a MoNbNi ternary alloy, wherein the Ni has a weight percentage ranging from 0.05% to 50%.

5. The thin film transistor as claimed in claimed 1, wherein the Mo of the molybdenum alloy layer has a weight percentage ranging from 30% to 95%, and other two metal elements have a weight percentage ranging from 0.10% to 40%.

6. The thin film transistor as claimed in claimed 1, wherein the active layer is a-Si or IGZO.

7. A method for manufacturing thin film transistor, wherein, comprising the steps as below:
a substrate providing step, providing a substrate;
a gate manufacturing step, manufacturing a gate on an upper surface of the substrate;
a gate insulation layer manufacturing step, manufacturing a gate insulation layer on an upper surface of the gate;
an active layer manufacturing step, manufacturing an active layer on an upper surface of the gate insulation layer;
a contact layer manufacturing step, manufacturing a contact layer on an upper surface of the active layer; and
a source/drain manufacturing step, manufacturing a source/drain on an upper surface of the contact layer and the gate insulation;
wherein, the gate layer manufacturing step comprises the step as below:
a metal barrier layer manufacturing step, manufacturing a metal barrier layer on an upper surface of the substrate; and
a conductive layer manufacturing step, manufacturing a conductive layer on an upper surface of the metal barrier layer;
the metal barrier layer is a molybdenum alloy layer, the molybdenum alloy layer comprises Mo and two other metal elements.

8. The method for manufacturing thin film transistor as claimed in claimed 7, wherein the two other metal elements are any two of W, Nd, Nb, and Ta.

9. The method for manufacturing thin film transistor as claimed in claimed 7, wherein the Mo of the molybdenum alloy layer has a weight percentage ranging from 30% to 95%, and other two metal elements have a weight percentage ranging from 0.10% to 40%.

10. The method for manufacturing thin film transistor as claimed in claimed 7, wherein the conductive layer and the metal barrier layer are etched by a copper acid etching solution of a hydrogen peroxide system to form a patterned gate.
